(19) United States
(12) Patent Application Publication
(10) Pub. No.: US 2026/0120772 A1
(43) Pub. Date: Apr. 30, 2026

(54) MEMORY APPARATUS AND OPERATION METHOD OF MEMORY APPARATUS

(71) Applicant: SK hynix Inc., Gyeonggi-do (KR)

(72) Inventor: Dae Yong KWON, Gyeonggi-do (KR)

(21) Appl. No.: 19/047,624

(22) Filed: Feb. 7, 2025

(30) Foreign Application Priority Data
Oct. 28, 2024 (KR) 10-2024-0148434

(51) Int. Cl. G11C 16/24; G11C 16/04

(52) U.S. Cl. CPC G11C 16/24; G11C 16/0483

(57) ABSTRACT

A memory apparatus may include a voltage generation circuit configured to sequentially generate a plurality of data determination voltages at different levels based on a voltage control signal, a line driving circuit configured to sequentially drive a selected word line to the plurality of data determination voltages, a page buffer configured to generate a sensing detection signal when a memory cell connected to the selected word line is turned on, and a data counting circuit configured to perform a counting operation based on the voltage control signal, stop the counting operation based on the sensing detection signal, and provide the page buffer with a counting value according to the counting operation.

### CROSS-REFERENCE TO RELATED APPLICATION

This application claims priority under 35 U.S.C. § 119 (a) to Korean Patent Application No. 10-2024-0148434 filed on Oct. 28, 2024, which is incorporated herein by reference in its entirety.

### BACKGROUND

### 1. Technical Field

Embodiments of the present disclosure relate to an integrated circuit technology, and, to a memory apparatus and an operation method thereof.

### 2. Related Art

Recently, with the miniaturization, low power consumption, high performance, diversification, and the like of electronic devices, there is a demand for semiconductor apparatuses capable of storing information in various electronic appliances such as computers and portable communication devices. The semiconductor apparatuses may be roughly classified into volatile memory apparatuses and nonvolatile memory apparatuses. The volatile memory apparatus has a high data processing speed, but has a disadvantage in that power needs to be continuously supplied in order to retain stored data, and the nonvolatile memory apparatus does not need to be continuously supplied with power in order to retain stored data, but has a disadvantage in that a data processing speed is low.

Accordingly, research is being conducted to improve a data processing speed, that is, an operation speed, of the nonvolatile memory apparatus.

### SUMMARY

In an embodiment of the present disclosure, a memory apparatus may include a voltage generation circuit configured to sequentially generate a plurality of data determination voltages at different levels based on a voltage control signal; a line driving circuit configured to sequentially drive a selected word line to the plurality of data determination voltages; a page buffer configured to generate a sensing detection signal when a memory cell connected to the selected word line is turned on; and a data counting circuit configured to perform a counting operation based on the voltage control signal, stop the counting operation based on the sensing detection signal, and provide the page buffer with a counting value according to the counting operation.

In another embodiment of the present disclosure, a memory apparatus may include a line driving circuit configured to provide a plurality of data determination voltages at different levels to a selected word line to drive the selected word line; at least one sensing latch configured to generate a sensing detection signal when a memory cell connected to the selected word line is turned on; a data counting circuit configured to perform a counting operation whenever a voltage level for driving the selected word line is changed, stop the counting operation based on the sensing detection signal, and generate a counting value according to the counting operation; and at least one data latch circuit configured to store the counting value and output the stored counting value as data.

In a still another embodiment of the present disclosure, an operation method of a memory apparatus may include sequentially providing, during a read operation, data determination voltages at different levels to a selected word line; performing a counting operation whenever levels of the data determination voltages are changed; detecting a voltage level of a bit line of a memory cell connected to the selected word line; stopping the counting operation when the detected voltage level of the bit line is lower than a set level; and outputting a counting value corresponding to the stopped counting operation as data.

### BRIEF DESCRIPTION OF THE DRAWINGS

FIG. 1 is a diagram for describing the configuration of a memory apparatus in accordance with an embodiment of the present disclosure.

FIG. 2 is a diagram for describing the configuration of a bank of the memory apparatus in accordance with an embodiment of the present disclosure.

FIG. 3 is a diagram for describing a page buffer of the memory apparatus in accordance with an embodiment of the present disclosure.

FIG. 4 is a diagram for describing an operation of determining data stored in a memory cell of the memory apparatus in accordance with an embodiment of the present disclosure.

FIG. 5 is a diagram for describing an operation of the memory apparatus in accordance with an embodiment of the present disclosure.

FIG. 6 is a diagram for describing the operation of a code conversion circuit of the memory apparatus in accordance with an embodiment of the present disclosure.

FIG. 7 is a diagram for describing an effect of the memory apparatus in accordance with an embodiment of the present disclosure.

FIG. 8 is a diagram for describing the configuration of a memory apparatus in accordance with another embodiment of the present disclosure.

### DETAILED DESCRIPTION

Various embodiments of the present disclosure are directed to providing a memory apparatus that can improve a read operation speed and an operation method thereof.

The speed of a memory apparatus can be increased by increasing the speed of a read operation.

Hereafter, embodiments in accordance with the technical spirit of the present disclosure will be described with reference to the accompanying drawings.

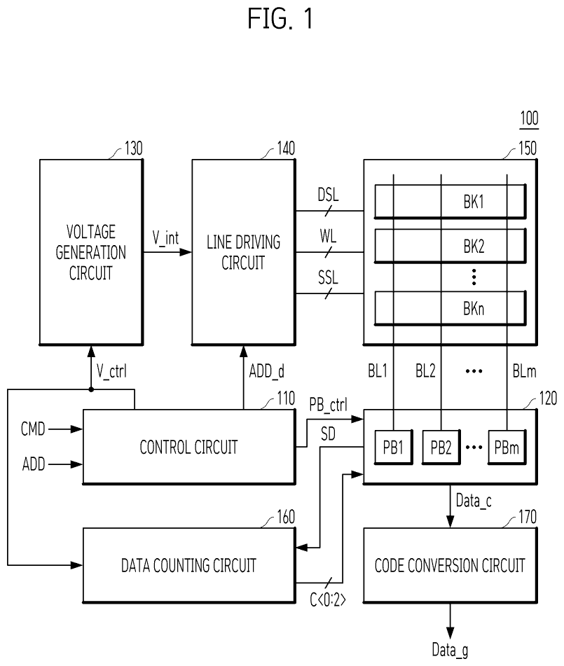

FIG. 1 is a diagram for describing the configuration of a memory apparatus 100 in accordance with an embodiment of the present disclosure.

Referring to FIG. 1, the memory apparatus 100 may include a control circuit 110, a page buffer group 120, a voltage generation circuit 130, a line driving circuit 140, a memory cell array 150, and a data counting circuit 160. The memory apparatus 100 may additionally include a code conversion circuit 170.

In an embodiment, the control circuit 110 may control the page buffer group 120, the voltage generation circuit 130, the line driving circuit 140, and the data counting circuit 160 to program data in the memory cell array 150 or to erase data programmed in the memory cell array 150.

In an embodiment, the control circuit 110 may generate a page buffer control signal PB_ctrl based on a command signal CMD and an address signal ADD received from an external device (for example, a host), and provide the page buffer control signal PB_ctrl to the page buffer group 120.

In an embodiment, the control circuit 110 may generate a voltage control signal V_ctrl based on the command signal CMD, and provide the voltage control signal V_ctrl to the voltage generation circuit 130.

In an embodiment, the control circuit 110 may generate a driving address signal ADD_d based on the command signal CMD and the address signal ADD, and provide the driving address signal ADD_d to the line driving circuit 140.

In an embodiment, the page buffer group 120 may include a plurality of page buffers PB1, PB2, . . . , and PBm. The plurality of page buffers PB1, PB2, . . . , and PBm may be connected to a plurality of bit lines BL1, BL2, . . . , and BLm, where m is a natural number, respectively. Each of the plurality of page buffers PB1, PB2, . . . , and PBm may sense a data value stored in a memory cell through a bit line, and provide the sensed value to the data counting circuit 160 as a sensing detection signal SD. In addition, each of the plurality of page buffers PB1, PB2, . . . , and PBm may store counting values C<0:2> of the data counting circuit 160, and output the stored values as data Data_c of a first format.

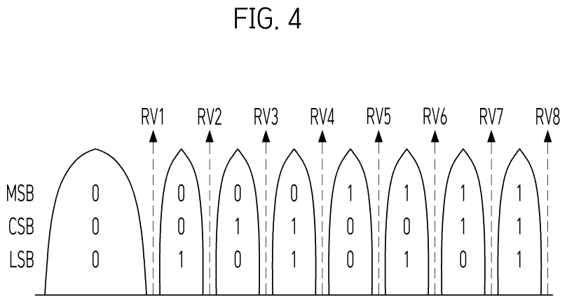

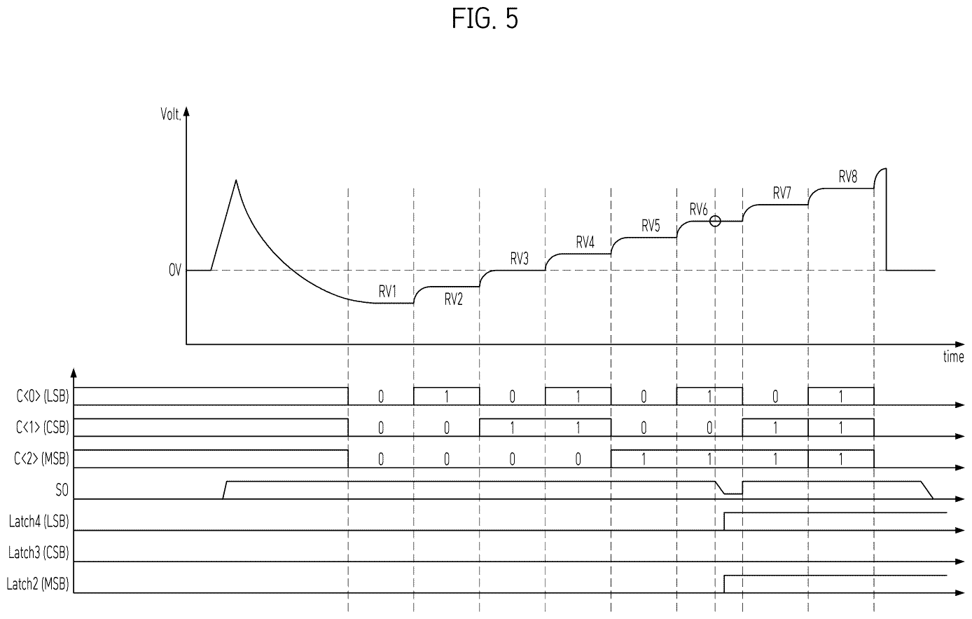

In an embodiment, the voltage generation circuit 130 may generate internal voltages V_int at various voltage levels based on the voltage control signal V_ctrl, and provide the internal voltages V_int to the line driving circuit 140. For example, during a read operation, the voltage generation circuit 130 may sequentially provide a plurality of data determination voltages RV1 to RV8 (illustrated in FIGS. 4 and 5) at different levels to the line driving circuit 140 as the internal voltages V_int.

In an embodiment, the line driving circuit 140 may drive drain select lines DSL, word lines WL, and source select lines SSL to the voltage level of the internal voltages V_int based on the driving address signal ADD_d. For example, the line driving circuit 140 may selectively drive the drain select lines DSL, the word lines WL, and the source select lines SSL to the voltage level of the internal voltages V_int based on the driving address signal ADD_d. In particular, during the read operation, the line driving circuit 140 may sequentially drive a word line WL selected according to the driving address ADD_d to voltage levels of a plurality of data determination voltages RV1 to RV8.

In an embodiment, the memory cell array 150 may include a plurality of memory blocks BK1, BK2, . . . , and BKn, where n is a natural number. Each of the plurality of memory blocks BK1, BK2, . . . , and BKn may be selected by the driven drain select lines DSL, the word lines WL, and the source select lines SSL, and memory strings of the selected memory block may be connected to the plurality of page buffers PB1, PB2, . . . , and PBm through the bit lines BL1, BL2, . . . , and BLm. In addition, each of the plurality of memory blocks BK1, BK2, . . . , and BKn may include a plurality of memory strings in which a plurality of memory cells are connected in series. Each of the plurality of memory strings may include a first select transistor (for example, a drain select transistor), a second select transistor (for example, a source select transistor), and a dummy cell in addition to the plurality of memory cells connected in series. The first select transistor may be turned on or off according to a voltage level of the drain select line DSL, and the second select transistor may be turned on or off according to a voltage level of the source select line SSL.

In an embodiment, the data counting circuit 160 may perform a counting operation based on the voltage control signal V_ctrl, and stop performing the counting operation when a page buffer of the page buffer group 120 connected to a selected bit line detects the turning-on of a memory cell. In addition, the data counting circuit 160 may transmit, to the page buffer, counting values C<0:2> when the counting operation has been stopped. For example, the data counting circuit 60 may perform a counting operation based on the voltage control signal V_ctrl, stop the counting operation based on the sensing detection signal SD, and provide the counting values C<0:2> to the page buffer having provided the sensing detection signal SD.

In an embodiment, the code conversion circuit 170 may convert the data Data_c of the first format output from the page buffer group 120 into data Data_g of a second format, and output the data Data_g. For example, the data Data_c of the first format output from the page buffer group 120 may have a data format in which the counting value sequentially increases. The data Data_g of the second format may be data of a gray code format.

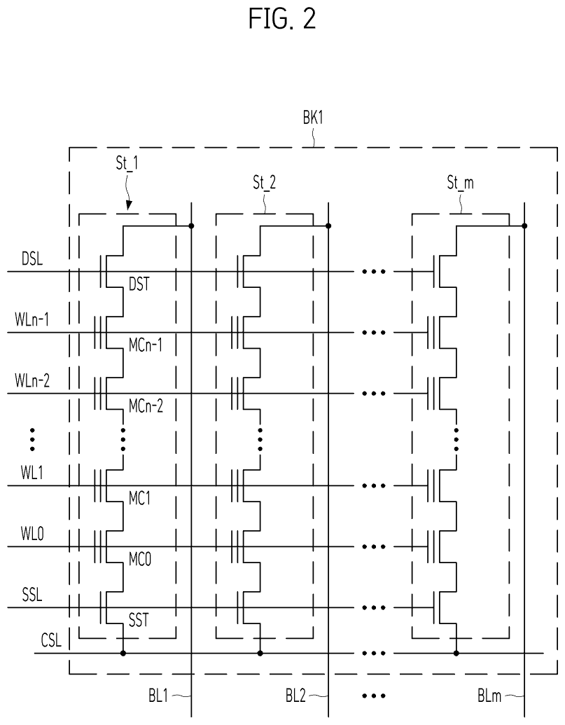

FIG. 2 is a diagram for describing the configuration of a bank of the memory apparatus in accordance with an embodiment of the present disclosure. In an embodiment, the bank may include at least one cell string. In FIG. 2, a plurality of cell strings included in one bank are described, but one bank is divided into cell string groups each including a plurality of cell strings and the bank includes at least one cell string group. In FIG. 2, one bank BK1 among a plurality of banks BK1 to BKn illustrated in FIG. 1 is merely described as an example, and it is noted that the embodiment is not limited thereto. In addition, in the memory apparatus in accordance with the embodiment of the present disclosure, a bank including a plurality of cell strings is described as an example, but the memory apparatus may also be used in a bank structure including memory cells connected between bit lines and word lines other than the cell string structure.

In an embodiment, the bank BK1 may include a plurality of cell strings St_0 to St_m. The plurality of cell strings St_0 to St_m may be connected between bit lines BL0 to BLm and a source line CSL. Each of the plurality of cell strings St_0 to St_m may include a drain select transistor DST, a plurality of cell transistors MC0 to MCn−1, and a source select transistor SST, which are connected in series between the bit line BL0 and the source line CSL. In such a case, because the configurations of the plurality of cell strings St_0 to St_m are the same except that the names of input signals or connected lines are different, the configuration of the cell string St_0 among the plurality of cell strings St_0 to St_m is representatively described.

In an embodiment, the cell string St_0 may include the drain select transistor DST, the plurality of cell transistors MC0 to MCn−1, and the source select transistor SST connected in series between the bit line BL0 and the source line CSL.

In an embodiment, the drain select transistor DST may have a gate to which the drain select line DSL is connected, and a drain to which the bit line BL0 is connected, and a source to which the cell transistor MCn−1 is connected.

In an embodiment, the plurality of cell transistors MC0 to MCn−1 may be connected in series between the drain select transistor DST and the source select transistor SST, and each of a plurality of word lines WL0 to WLn−1 may be connected to a corresponding gate. Each of the plurality of cell transistors MC0 to MCn−1 may serve as a memory cell in which data is programmed and erased.

Hereinafter, each of the plurality of cell transistors MC0 to MC_n−1 may be referred to as a memory cell.

In an embodiment, the source select transistor SST may have a gate to which the source select line SSL is connected, and a drain to which the cell transistor MC0 is connected, and a source to which the source line CSL is connected.

As described above, the page buffer group 120 may include the plurality of page buffers PB1 to PBm. The plurality of page buffers PB1 to PBm may be connected to the plurality of bit lines BL0 to BLm, respectively. The plurality of page buffers PB1 to PBm may sense threshold voltages of the memory cells MC0 to MCn−1 through the connected bit lines BL0 to BLm, respectively. The page buffer group 120 may provide the data counting circuit 160 with a threshold voltage sensing result of a memory cell sensed by at least one of the plurality of page buffers PB1 to PBm, that is, a sensing detection signal SD.

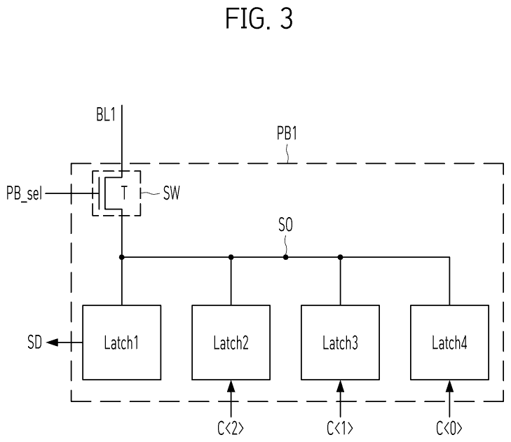

FIG. 3 is a diagram for describing the page buffer of the memory apparatus in accordance with an embodiment of the present disclosure. FIG. 3 illustrates one page buffer PB1 among the plurality of page buffers PB1 to PBm illustrated in FIG. 1 as an example, and the description of each of the plurality of page buffers PB1 to PBm may be replaced with the description of the page buffer PB1.

Referring to FIG. 3, the page buffer PB1 may include a plurality of latches Latch1 to Latch5 and a connection switch SW. For example, the page buffer PB1 may include first to fourth latches Latch1 to Latch4. Among the first to fourth latches Latch1 to Latch4, one latch may sense a threshold voltage of a memory cell connected to the bit line BL. In addition, among the first to fourth latches Latch1 to Latch4, the remaining latches may store counting values C<0:2> transmitted from the data counting circuit 160.

In an embodiment, the first to fourth latches Latch1 to Latch4 may be commonly connected to a sensing node SO. The connection switch SW may electrically connect or disconnect the bit line BL and the sensing node SO.

In an embodiment, the connection switch SW may electrically connect or disconnect the bit line BL and the sensing node SO based on a page buffer selection signal PB_sel. For example, the connection switch SW may electrically connect the bit line BL and the sensing node SO based on a page buffer selection signal PB_sel at a first level. The connection switch SW may electrically disconnect the bit line from the sensing node SO based on a page buffer selection signal PB_sel at a second level that is different from the first level. The first level may mean a high level and the second level may mean a low level. In the following description, the first level is a high level and the second level is a low level; however, the first level of the page buffer selection signal PB_sel may mean a level at which the connection switch SW is turned on, and the second level may mean a level at which the connection switch SW is turned off. The page buffer selection signal PB_sel may be included in the page buffer control signal PB_ctrl.

In an embodiment, the first to fourth latches Latch1 to Latch4 may be commonly connected to the sensing node SO. The first latch Latch1 may be a latch that is most closely connected to the bit line BL.

In an embodiment, in a state in which the bit line BL and the sensing node SO are electrically connected, the first latch Latch1 may sense the voltage level of the sensing node SO that changes according to the voltage level of the bit line BL. That is, the first latch Latch1 may detect the voltage level of the bit line BL through the voltage level of the sensing node SO.

In an embodiment, the first latch Latch1 may detect the voltage level of the bit line BL, and store and output information on whether a memory cell is turned on. For example, when a memory cell is turned on and the voltage level of a bit line is reduced to a set voltage level or less, that is, when the voltage level of the sensing node SO is reduced to a voltage level or less corresponding to the set voltage level, the first latch Latch1 may store the second level. On the other hand, when the memory cell is not turned on and the voltage level of the bit line does not fall, that is, when the voltage level of the sensing node SO is not changed, the first latch Latch1 may store the first level. Accordingly, because the first latch Latch1 performs a function of sensing whether the memory cell is turned on, it may be referred to as a sensing latch. In addition, the first latch Latch1 may transmit the stored level to the data counting circuit 160 as the sensing detection signal SD.

In an embodiment, the second to fourth latches Latch2 to Latch4 may store counting values C<0:2>. For example, the second latch Latch2 may store the counting value C<2>. The third latch Latch3 may store the counting value C<1>. The fourth latch Latch4 may store the counting value C<0> as data. Accordingly, because the second to fourth latches Latch2 to Latch4 are latches that output the counting values C<0:2> as data of a read operation, they may be referred to as data latches. The counting values C<0:2> may be values transmitted from the counting data circuit 160.

FIG. 4 is a diagram for describing an operation of determining data stored in a memory cell of the memory apparatus in accordance with an embodiment of the present disclosure. The memory cell is a memory cell that stores at least 1-bit data. In FIG. 4, a memory cell that stores 3-bit data is illustrated as an example of the memory cell; however, the embodiment is not limited thereto.

Referring to FIG. 4, the memory cell may store data represented by a least significant bit LSB, a center significant bit CSB, and a most significant bit MSB. Accordingly, the threshold voltage of the memory cell may include eight threshold voltages at different levels.

In an embodiment, a memory cell with the lowest threshold voltage may store data in which the least significant bit LSB, the center significant bit CSB, and the most significant bit MSB are all at a low level 0. In such a case, the level of the threshold voltage of the memory cell with the lowest threshold voltage may be lower than the level of a first data determination voltage RV1 at the lowest level. The lowest threshold voltage among the threshold voltages of the memory cell may be referred to as a first threshold voltage, and the first data determination voltage RV1 with the lowest voltage level may be referred to as a first data determination voltage.

In an embodiment, a memory cell with a second threshold voltage may have a threshold voltage higher than the first threshold voltage. The level of the second threshold voltage may be higher than the level of the first data determination voltage RV1 and lower than the level of a second data determination voltage RV2. The memory cell with the second threshold voltage may store data in which the least significant bit LSB is at a high level 1 and the center significant bit CSB and the most significant bit MSB are at a high level 1.

In an embodiment, a memory cell with a third threshold voltage may have a threshold voltage higher than the second threshold voltage. The level of the third threshold voltage may be higher than the level of the second data determination voltage RV2 and lower than the level of a third data determination voltage RV3. The memory cell with the third threshold voltage may store data in which the least significant bit LSB is at a low level 0, the center significant bit CSB is at a high level 1, and the most significant bit MSB is at a low level 0.

In an embodiment, a memory cell with a fourth threshold voltage may have a threshold voltage higher than the third threshold voltage. The level of the fourth threshold voltage may be higher than the level of the third data determination voltage RV3 and lower than the level of a fourth data determination voltage RV4. The memory cell with the fourth threshold voltage may store data in which the least significant bit LSB is at a high level 1, the center significant bit CSB is at a high level 1, and the most significant bit MSB is at a low level 0.

In an embodiment, a memory cell with a fifth threshold voltage may have a threshold voltage higher than the fourth threshold voltage. The level of the fifth threshold voltage may be higher than the level of the fourth data determination voltage RV4 and lower than the level of a fifth data determination voltage RV5. The memory cell with the fifth threshold voltage may store data in which the least significant bit LSB is at a low level 0, the center significant bit CSB is at a low level 0, and the most significant bit MSB is at a high level 1.

In an embodiment, a memory cell with a sixth threshold voltage may have a threshold voltage higher than the fifth threshold voltage. The level of the sixth threshold voltage may be higher than the level of the fifth data determination voltage RV5 and lower than the level of a sixth data determination voltage RV6. The memory cell with the sixth threshold voltage may store data in which the least significant bit LSB is at a high level 1, the center significant bit CSB is at a low level 0, and the most significant bit MSB is at a high level 1.

In an embodiment, a memory cell with a seventh threshold voltage may have a threshold voltage higher than the sixth threshold voltage. The level of the seventh threshold voltage may be higher than the level of the sixth data determination voltage RV6 and lower than the level of a seventh data determination voltage RV7. The memory cell with the seventh threshold voltage may store data in which the least significant bit LSB is at a low level 0, the center significant bit CSB is at a high level 1, and the most significant bit MSB is at a high level 1.

In an embodiment, a memory cell with an eighth threshold voltage may have a threshold voltage higher than the seventh threshold voltage. The level of the eighth threshold voltage may be higher than the level of the seventh data determination voltage RV7 and lower than the level of an eighth data determination voltage RV8. The memory cell with the eighth threshold voltage may store data in which the least significant bit LSB, the center significant bit CSB, and the most significant bit MSB are all at a high level 1.

In an embodiment, the memory apparatus in accordance with an embodiment of the present disclosure described above operates as follows.

In an embodiment, during a read operation, a memory cell to be subjected to the read operation may be selected by the driving address signal ADD_d according to the address signal ADD.

In an embodiment, a word line connected to a selected memory cell, that is, a selected word line sequentially may receive the first to eighth data determination voltages RV1 to RV8. As illustrated in FIG. 4, the first to eighth data determination voltages RV1 to RV8 may be voltages whose voltage levels sequentially increase. In such a case, the data counting circuit 160 may receive a voltage control signal V_ctrl for controlling the provision of the first to eighth data determination voltages RV1 to RV8. The data counting circuit 160 may perform an up-counting operation of increasing the counting values C<0:2> based on the voltage control signal V_ctrl whenever the level of a data determination voltage provided to a word line is changed.

In an embodiment, a memory cell connected to a word line that sequentially receives the first to eighth data determination voltages RV1 to RV8 may be turned on when a voltage level higher than a threshold voltage level of the memory cell is provided to the word line. When the memory cell is turned on, the level of a bit line connected to the memory cell may be lowered than a set voltage level. In such a case, the level stored in the first latch Latch1 of the page buffer connected to the bit line may be changed. For example, the level stored in the first latch Latch1 may be initialized to the first level and may be changed to the second level when the voltage level of the bit line is lower than the set voltage level. In such a case, the first latch Latch1 may transmit a sensing detection signal SD at the second level to the data counting circuit 160.

In an embodiment, the data counting circuit 160 having received the sensing detection signal SD at the second level may stop the counting operation, and transmit the counting values C<0:2> of the stopped counting operation to the second to fourth latches Latch2 to Latch4 of the page buffer.

In an embodiment, the counting values C<0:2> stored in the second to fourth latches Latch2 to Latch4 of the page buffer may be data stored in the memory cell, and may be output to an external device, for example, a memory controller (not illustrated), or provided to the code conversion circuit 170. In such a case, the data output from the page buffer may be data of a first format, and the data of the first format may be converted into data of a second format through the code conversion circuit 170 and may be output to the external device. The data of the first format may be data according to an up-counted counting value, and the data of the second format may be data according to a gray code.

The operation of the memory apparatus in accordance with an embodiment of the present disclosure that operates in this manner is described in more detail with reference to FIG. 5 as follows.

FIG. 5 is a diagram for describing the operation of the memory apparatus in accordance with an embodiment of the present disclosure. In such a case, a memory cell may be a memory cell with one of the first to eighth threshold voltages at different levels. The memory cell may also be a memory cell storing data corresponding to the sixth threshold voltage among the first to eighth threshold voltages.

Referring to FIG. 5, in order to determine data stored in a selected memory cell during a read operation, the first to eighth data determination voltages RV1 to RV8 may be sequentially provided to a word line connected to the selected memory cell, that is, a selected word line.

In an embodiment, whenever the first to eighth data determination voltages RV1 to RV8 are sequentially provided to the selected word line, the data counting circuit 160 may sequentially increase the counting values C<0:2>.

For example, when the control circuit 110 provides the data counting circuit 160 with a voltage control signal V_ctrl for instructing the voltage generation circuit 130 to generate the first data determination voltage RV1, the data counting circuit 160 may generate counting values C<0:2> of (0, 0, 0). The counting values C<0:2> may be described in the order of C<2>, C<1>, and C<0>. When the control circuit 110 provides the data counting circuit 160 with a voltage control signal V_ctrl for instructing the voltage generation circuit 130 to generate the second data determination voltage RV2, the data counting circuit 160 may generate counting values C<0:2> of (0, 0, 1). When the control circuit 110 provides the data counting circuit 160 with a voltage control signal V_ctrl for instructing the voltage generation circuit 130 to generate the third data determination voltage RV3, the data counting circuit 160 may generate counting values C<0:2> of (0, 1, 0). When the control circuit 110 provides the data counting circuit 160 with a voltage control signal V_ctrl for instructing the voltage generation circuit 130 to generate the fourth data determination voltage RV4, the data counting circuit 160 may generate counting values C<0:2> of (0, 1, 1). When the control circuit 110 provides the data counting circuit 160 with a voltage control signal V_ctrl for instructing the voltage generation circuit 130 to generate the fifth data determination voltage RV5, the data counting circuit 160 may generate counting values C<0:2> of (1, 0, 0). When the control circuit 110 provides the data counting circuit 160 with a voltage control signal V_ctrl for instructing the voltage generation circuit 130 to generate the sixth data determination voltage RV6, the data counting circuit 160 may generate counting values C<0:2> of (1, 0, 1). When the control circuit 110 provides the data counting circuit 160 with a voltage control signal V_ctrl for instructing the voltage generation circuit 130 to generate the seventh data determination voltage RV7, the data counting circuit 160 may generate counting values C<0:2> of (1, 1, 0). When the control circuit 110 provides the data counting circuit 160 with a voltage control signal V_ctrl for instructing the voltage generation circuit 130 to generate the eighth data determination voltage RV8, the data counting circuit 160 may generate counting values C<0:2> of (1, 1, 1).

As described above, because the memory cell is a memory cell storing data corresponding to the sixth threshold voltage, when the sixth data determination voltage RV6 is provided to the selected word line, the memory cell may be turned on. The turned-on memory cell may lower the voltage level of the bit line below the set voltage level, and thus the voltage level of the sensing detection signal SD may be changed from the first level to the second level.

In an embodiment, the sensing detection signal SD whose voltage level has changed may stop the counting operation of the data counting circuit 160. Accordingly, the data counting circuit 160 may transmit, to the second to fourth latches Latch2 to Latch4 of the page buffer, the counting values C<0:2> of (1, 0, 1) when the sixth data determination voltage RV6 has been provided. The second latch Latch2 may store a level corresponding to the least significant bit LSB, that is, a high level, the third latch Latch3 may store a level corresponding to the center significant bit CSB, that is, a low level, and the fourth latch Latch4 may stores a level corresponding to the most significant bit MSB, that is, a high level.

In this way, the data of the first format according to the least significant bit LSB, the center significant bit CSB, and the most significant bit MSB stored in the second to fourth latches Latch2 to Latch4 may be provided to the external device or the code conversion circuit 170.

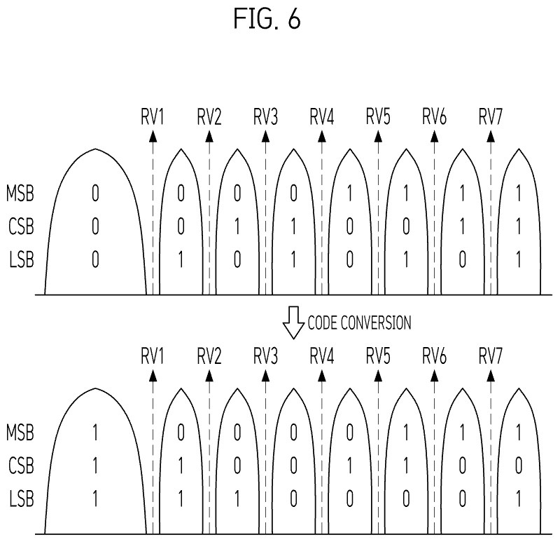

FIG. 6 is a diagram for describing the operation of the code conversion circuit of the memory apparatus in accordance with an embodiment of the present disclosure.

In an embodiment, the code conversion operation of the code conversion circuit 170 illustrated in FIG. 6 may be an operation of converting data of the first format having code values MSB, CSB, and LSB in which the counting values C<0:2> increase sequentially into a gray code.

In an embodiment, the code conversion circuit 170 may convert data (0, 0, 0) of the first format into data (1, 1, 1) of the second format. The code conversion circuit 170 may convert data (0, 0, 1) of the first format into data (0, 1, 1) of the second format. The code conversion circuit 170 may convert data (0, 1, 0) of the first format into data (0, 0, 1) of the second format. The code conversion circuit 170 may convert data (0, 1, 1) of the first format into data (0, 0, 0) of the second format. The code conversion circuit 170 may convert data (1, 0, 0) of the first format into data (0, 1, 0) of the second format. The code conversion circuit 170 may convert data (1, 0, 1) of the first format into data (1, 1, 0) of the second format. The code conversion circuit 170 may convert data (1, 1, 0) of the first format into data (1, 0, 0) of the second format. The code conversion circuit 170 may convert data (1, 1, 1) of the first format into data (1, 0, 1) of the second format.

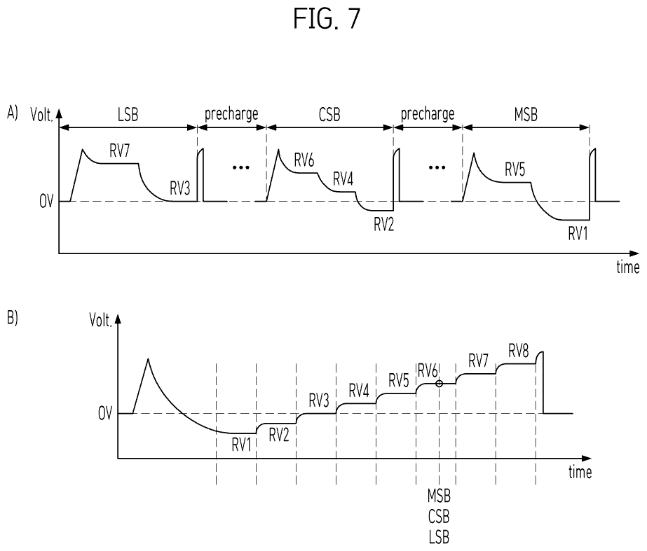

FIG. 7 is a diagram for describing an effect of the memory apparatus in accordance with an embodiment of the present disclosure.

In (A) of FIG. 7, in order to determine the least significant bit LSB stored in the memory cell, the seventh and third data determination voltages RV7 and RV3 may be sequentially provided to the selected word line, and then the selected word line may be precharged. The sixth data determination voltage RV6, the fourth data determination voltage RV4, and the second data determination voltage RV2 may be sequentially provided to the precharged word line. Subsequently, the word line may be precharged again. The fifth and first data determination voltages RV5 and RV1 may be provided to the precharged word line.

In this way, the data determination method illustrated in (A) of FIG. 7 may provide data determination voltages corresponding to word lines in order to sequentially determine the least significant bit LSB, the center significant bit CSB, and the most significant bit MSB, and may include a period for precharging the word line before the data determination voltage is provided in order to determine a next bit.

In (B) of FIG. 7, the counting values C<0:2> may be increased whenever the level of the data determination voltage provided to the selected word line is changed, and the counting values C<0:2>, when the memory cell is turned on according to the voltage level of the selected word line, may be provided as the least significant bit LSB, the center significant bit CSB, and the most significant bit MSB stored in the memory cell.

Accordingly, unlike (A) of FIG. 7, in (B) of FIG. 7, the least significant bit LSB, the center significant bit CSB, and the most significant bit MSB stored in the memory cell may be simultaneously determined. In addition, because the least significant bit LSB, the center significant bit CSB, and the most significant bit MSB are simultaneously determined, a precharge period for determining a next bit after determining a previous bit may not be needed.

Therefore, the speed of the read operation according to the data determination operation of the memory apparatus in accordance with the embodiment of the present disclosure can be higher than the speed in the method (A) of FIG. 7.

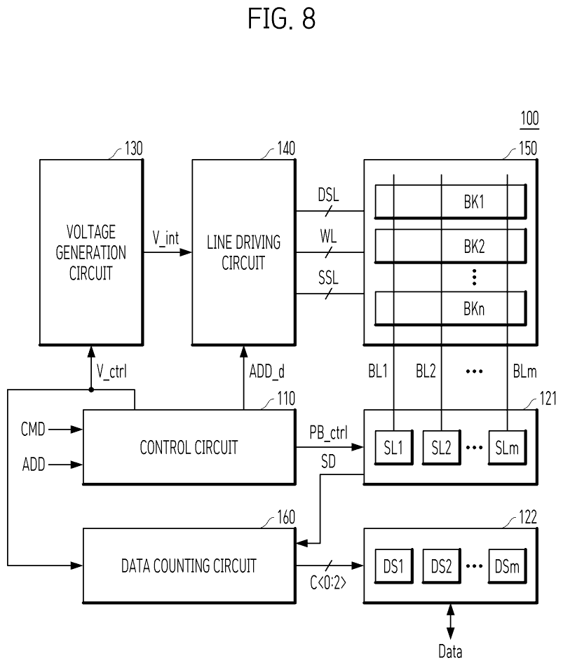

FIG. 8 is a diagram for describing the configuration of a memory apparatus in accordance with another embodiment of the present disclosure.

Referring to FIG. 8, the memory apparatus may include a control circuit 110, a sensing latch group 121, a data latch group 122, a voltage generation circuit 130, a line driving circuit 140, a memory cell array 150, and a data counting circuit 160.

In an embodiment, the control circuit 110 may control the sensing latch group 121, the data latch group 122, the voltage generation circuit 130, the line driving circuit 140, and the data counting circuit 160 to program and store data in the memory cell array 150, or to output data stored in the memory cell array 150.

In an embodiment, the control circuit 110 may generate a page buffer control signal PB_ctrl based on a command signal CMD and an address signal ADD received from an external device (for example, a host), and provide the page buffer control signal PB_ctrl to the page buffer group 120.

In an embodiment, the control circuit 110 may generate a voltage control signal V_ctrl based on the command signal CMD and provide the voltage control signal V_ctrl to the voltage generation circuit 130.

In an embodiment, the control circuit 110 may generate a driving address signal ADD_d based on the command signal CMD and the address signal ADD, and provide the driving address signal ADD_d to the line driving circuit 140.

In an embodiment, the sensing latch group 121 may include a plurality of sensing latches SL1, SL2, . . . , and SLm. The plurality of sensing latches SL1, SL2, . . . , and SLm may be connected to a plurality of bit lines BL1, BL2, . . . , and BLm, where m is a natural number, respectively. Each of the plurality of sensing latches SL1, SL2, . . . , and SLm may sense a data value stored in a memory cell through a bit line, store the sensed value as a sensing detection signal SD, and output the sensing detection signal SD. The sensing detection signal SD may be provided to the data counting circuit 160.

In an embodiment, the data latch group 122 may include a plurality of data latch circuits DS1, DS2, . . . , and DSm that store counting values C<0:2> provided from the data counting circuit 160. The plurality of data latch circuits DS1, DS2, . . . , and DSm may include data latches that store bits C<0>, C<1>, and C<2> of the counting values C<0:2>, respectively. The counting values C<0:2> stored in the data latch group 122 may be output as data according to a read operation.

In an embodiment, the voltage generation circuit 130 may generate internal voltages V_int at various voltage levels based on the voltage control signal V_ctrl, and provide the internal voltages V_int to the line driving circuit 140. For example, during the read operation, the voltage generation circuit 130 may sequentially provide the plurality of data determination voltages RV1 to RV8 (illustrated in FIGS. 4 and 5) at different levels to the line driving circuit 140 as the internal voltages V_int.

In an embodiment, the line driving circuit 140 may drive drain select lines DSL, word lines WL, and source select lines SSL to the voltage levels of the internal voltages V_int based on the driving address signal ADD_d. For example, the line driving circuit 140 may selectively drive the drain select lines DSL, the word lines WL, and the source select lines SSL to the voltage levels of the internal voltages V_int based on the driving address signal ADD_d. In particular, during the read operation, the line driving circuit 140 may sequentially drive a word line WL selected according to the driving address ADD_d to the voltage levels of the plurality of data determination voltages RV1 to RV8.

In an embodiment, the memory cell array 150 may include a plurality of memory blocks BK1, BK2, . . . , and BKn, where n is a natural number. Each of the plurality of memory blocks BK1, BK2, . . . , and BKn may be selected by the driven drain select lines DSL, word lines WL, and source select lines SSL, and memory strings of the selected memory block may be connected to a plurality of page buffers PB1, PB2, . . . , and PBm through the bit lines BL1, BL2, . . . , and BLm. In addition, each of the plurality of memory blocks BK1, BK2, . . . , and BKn may include a plurality of memory strings in which a plurality of memory cells are connected in series. Each of the plurality of memory strings may include a first select transistor (for example, a drain select transistor), a second select transistor (for example, a source select transistor), and a dummy cell in addition to the plurality of memory cells connected in series. The first select transistor may be turned on or off according to a voltage level of the drain select line DSL, and the second select transistor may be turned on or off according to a voltage level of the source select line SSL.

In an embodiment, the data counting circuit 160 may perform a counting operation based on the voltage control signal V_ctrl, and stop performing the counting operation when a sensing latch of the sensing latch group 121 connected to a selected bit line detects the turning-on of a memory cell. In addition, the data counting circuit 160 may transmit, to the data latch group 121, counting values C<0:2> when the counting operation has been stopped. For example, the data counting circuit 160 may perform a counting operation based on the voltage control signal V_ctrl, stop the counting operation based on a sensing detection signal SD that is an output of a sensing latch connected to a selected bit line, and provide to the data latch group 122 with counting values C<0:2> of the stopped counting operation.

In an embodiment, the sensing latch group 121 and the data latch group 122 of the memory apparatus illustrated in FIG. 8 may be referred to as follows: the sensing latch Latch1 and the data latches Latch2 to Latch4 included in each of the page buffers of the page buffer group 120 included in the memory apparatus illustrated in FIG. 1 are distinguished, and a group including sensing latches SL1, SL2, . . . , and SLm may be referred to as the group 121, and a group including data latch circuits DS1, DS2, . . . , and DSm including the data latches Latch2 to Latch4 may be referred to as the group 122.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

Furthermore, the embodiments may be combined to form additional embodiments.

What is claimed is:

1. A memory apparatus comprising:
a voltage generation circuit configured to sequentially generate a plurality of data determination voltages at different levels based on a voltage control signal;
a line driving circuit configured to sequentially drive a selected word line to the plurality of data determination voltages;
a page buffer configured to generate a sensing detection signal when a memory cell connected to the selected word line is turned on; and
a data counting circuit configured to perform a counting operation based on the voltage control signal, stop the counting operation based on the sensing detection signal, and provide the page buffer with a counting value according to the counting operation.

2. The memory apparatus of claim 1, wherein the voltage generation circuit is configured to generate the plurality of data determination voltages in an order of a lowest data determination voltage to a highest data determination voltage based on the voltage control signal.

3. The memory apparatus of claim 2, wherein the line driving circuit is configured to sequentially drive the selected word line in an order of the lowest data determination voltage to the highest data determination voltage.

4. The memory apparatus of claim 3, wherein the page buffer comprises a plurality of latches, and
wherein one of the plurality of latches is configured to generate the sensing detection signal when a bit line and a sensing node are connected and a level of the bit line is reduced to a set level or less.

5. The memory apparatus of claim 4, wherein remaining latches among the plurality of latches are configured to store the counting value.

6. The memory apparatus of claim 5, wherein the data counting circuit is configured to up-count the counting value based on the voltage control signal whenever levels of the plurality of data determination voltages provided to the selected word line are changed.

7. The memory apparatus of claim 6, wherein the data counting circuit is configured to stop up-counting of the counting value when the sensing detection signal is received, and provide the counting value corresponding to the stopped up-counting to the remaining latches of the page buffer.

8. The memory apparatus of claim 7, further comprising:
a code conversion circuit configured to convert data stored in the remaining latches into data according to a gray code to output the converted data.

9. A memory apparatus comprising:
a line driving circuit configured to provide a plurality of data determination voltages at different levels to a selected word line to drive the selected word line;
at least one sensing latch configured to generate a sensing detection signal when a memory cell connected to the selected word line is turned on;
a data counting circuit configured to perform a counting operation whenever a voltage level for driving the selected word line is changed, stop the counting operation based on the sensing detection signal, and generate a counting value according to the counting operation; and
at least one data latch circuit configured to store the counting value and output the stored counting value as data.

10. The memory apparatus of claim 9, wherein the line driving circuit is configured to provide the plurality of data determination voltages to the selected word line in an order of a lowest data determination voltage to a highest data determination voltage to drive the selected word line.

11. The memory apparatus of claim 10, wherein, when a voltage level of a bit line connected to the memory cell is reduced to a set level or less, the sensing latch is configured to determine that the memory cell is turned on.

12. The memory apparatus of claim 11, wherein the data counting circuit is configured to up-count the counting value whenever levels of the plurality of data determination voltages provided to the selected word line are changed.

13. The memory apparatus of claim 11, wherein the data counting circuit is configured to stop up-counting of the counting value when the sensing detection signal is received, and provide the counting value corresponding to the stopped up-counting to the data latch circuit of the at least one data latch circuit.

14. The memory apparatus of claim 13, wherein the at least one data latch circuit is configured to store the counting value.

15. An operation method of a memory apparatus, the operation method comprising:
sequentially providing, during a read operation, data determination voltages at different levels to a selected word line;
performing a counting operation whenever levels of the data determination voltages are changed;
detecting a voltage level of a bit line of a memory cell connected to the selected word line;
stopping the counting operation when the detected voltage level of the bit line is lower than a set level; and
outputting a counting value corresponding to the stopped counting operation as data.

16. The operation method of a memory apparatus of claim 15, wherein sequentially providing the data determination voltages at different levels comprises providing the data determination voltages in an order of a lowest data determination voltage to a highest data determination voltage.

17. The operation method of a memory apparatus of claim 16, wherein performing the counting operation comprises up-counting the counting value.
